(19) United States
(12) Patent Application Publication
(10) Pub. No.: US 2026/0162937 A1
(43) Pub. Date: Jun. 11, 2026

(54) PLASMA PROCESSING APPARATUS AND PLASMA GENERATION METHOD

(71) Applicant: Tokyo Electron Limited, Tokyo (JP)

(72) Inventor: Takuma HASHIMOTO, Nirasaki City (JP)

(21) Appl. No.: 19/405,654

(22) Filed: Dec. 2, 2025

(30) Foreign Application Priority Data
Dec. 10, 2024 (JP) 2024-215857

(51) Int. Cl. H01J 37/32; H01P 7/04

(52) U.S. Cl. CPC H01J 37/321; H01P 7/04

(57) ABSTRACT

A plasma processing apparatus includes: a chamber having a plasma generation space, an emitter formed in an annular shape and disposed above the chamber, and a resonator configured to supply an electromagnetic wave to the emitter, wherein the resonator includes a waveguide through which the electromagnetic wave generated based on radio-frequency power propagates, and a plurality of slots configured to electromagnetically couple the waveguide and the emitter, wherein the plurality of slots are formed of a plurality of partial grooves extending in a circumferential direction of the emitter, wherein a plurality of impedance varying mechanisms for changing the impedance of each slot are disposed to correspond to each slot, wherein a plurality of coaxial tubes are disposed between each impedance varying mechanism and the corresponding slot, and wherein each impedance varying mechanism is attached to an end of the coaxial tube opposite the corresponding slot.

### CROSS-REFERENCE TO RELATED APPLICATION

This application is based upon and claims the benefit of priority from Japanese Patent Application No. 2024-215857, filed on Dec. 10, 2024, the entire content of which is incorporated herein by reference.

### TECHNICAL FIELD

The present disclosure relates to a plasma processing apparatus and a plasma generation method.

### BACKGROUND

A plasma processing apparatus is known in which a radio-frequency power supply supplies a radio-frequency wave to an input portion through a waveguide of a cylindrical waveguide portion. In this plasma processing apparatus, a resonator of the waveguide portion extends in an extension direction of a central axis of the waveguide portion and has a waveguide that extends in a circumferential direction around the central axis of the waveguide portion. This waveguide is connected to the input portion that extends in the circumferential direction, and the radio-frequency wave is introduced into a processing space from the input portion. When the radio-frequency wave is introduced into the processing space, a gas in the processing space is excited and plasma is generated from the gas.

### PRIOR ART DOCUMENT

### Patent Document

Patent Document 1: Japanese Laid-open Patent Publication No. 2020-092031

### SUMMARY

According to an embodiment of the present disclosure, there is provided a plasma processing apparatus including: a chamber having a plasma generation space, a first emitter formed in an annular shape and disposed above the chamber, and a resonator configured to supply an electromagnetic wave to the first emitter, wherein the resonator includes a waveguide through which the electromagnetic wave generated based on radio-frequency power by a radio-frequency power supply propagates, and a plurality of slots configured to electromagnetically couple the waveguide and the first emitter, wherein the plurality of slots are formed of a plurality of partial grooves extending in a circumferential direction of the first emitter, wherein a plurality of impedance varying mechanisms for changing the impedance of each of the plurality of first slots are disposed to correspond to each of the plurality of first slots, wherein a plurality of coaxial tubes are disposed between each of the impedance varying mechanisms and the corresponding first slots, and wherein each of the impedance varying mechanisms is attached to an end of the coaxial tube opposite the corresponding first slot.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical cross-sectional view schematically illustrating a configuration of a plasma processing apparatus according to an embodiment of the present disclosure.

FIG. 2 is a horizontal cross-sectional view taken along line II-II in FIG. 1.

FIGS. 3A and 3B are diagrams illustrating a positional relationship between a node of a standing wave and a coaxial tube connection portion when the standing wave is generated in an entire waveguide.

FIG. 4 is a partially enlarged cross-sectional view for explaining a length of the waveguide in a coaxial tube.

FIG. 5 is a diagram for explaining a simulation model of the plasma processing apparatus used to calculate a plasma density distribution in a plasma generation space.

FIG. 6 is a graph showing a distribution of electric field intensity formed in the plasma generation space calculated using the simulation model of FIG. 5.

FIGS. 7A and 7B are diagrams for explaining a change in a position of the coaxial tube connection portion in the simulation model of FIG. 5.

FIGS. 8A to 8C are graphs showing the distribution of electric field intensity in the plasma generation space calculated using a simulation model in which the position of the coaxial tube connection portion is changed in the vertical direction.

FIG. 9 is a diagram for explaining a change in the position of the coaxial tube connection portion and a change in a length of the coaxial tube in the simulation model of FIG. 5.

FIGS. 10A to 10I are graphs showing the distribution of electric field intensity in the plasma generation space calculated using a simulation model in which the position of the coaxial tube connection portion, a frequency of an input electromagnetic wave, and the length of the coaxial tube are changed.

FIGS. 11A to 11F are graphs showing the distribution of electric field intensity in the plasma generation space calculated using a simulation model in which the position of the coaxial tube connection portion, the frequency of the input electromagnetic wave, and the length of the coaxial tube are changed.

FIGS. 12A and 12B are graphs showing the distribution of electric field intensity in the plasma generation space calculated using a simulation model in which the position of the coaxial tube connection portion and the frequency of the input electromagnetic wave are changed.

FIG. 13 is a diagram for explaining a configuration of a first modification of the plasma processing apparatus.

FIGS. 14A to 14I are graphs showing the distribution of electric field intensity in the plasma generation space calculated using a simulation model of the plasma processing apparatus in which an impedance of each impedance gradual varying mechanism is changed.

FIG. 15 is a diagram for explaining a configuration of a second modification of the plasma processing apparatus.

FIGS. 16A to 16I are graphs showing the distribution of electric field intensity in the plasma generation space calculated using a simulation model of the plasma processing apparatus in which a capacitance of each variable capacitor mechanism and an inductance of each variable inductor mechanism are changed.

FIG. 17 is a horizontal cross-sectional view for explaining a configuration of a third modification of the plasma processing apparatus.

FIG. 18 is a graph showing the distribution of electric field intensity in the plasma generation space calculated using a simulation model of the third modification of the plasma processing apparatus.

FIGS. 19A to 19C are graphs showing the distribution of electric field intensity in the plasma generation space when the position of the coaxial tube connection portion is changed in the vertical direction in the simulation model of the third modification of the plasma processing apparatus.

FIGS. 20A to 20F are diagrams for explaining specific configurations of the switch, the gradual impedance varying mechanism, the variable capacitor mechanism, and the variable inductor mechanism.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

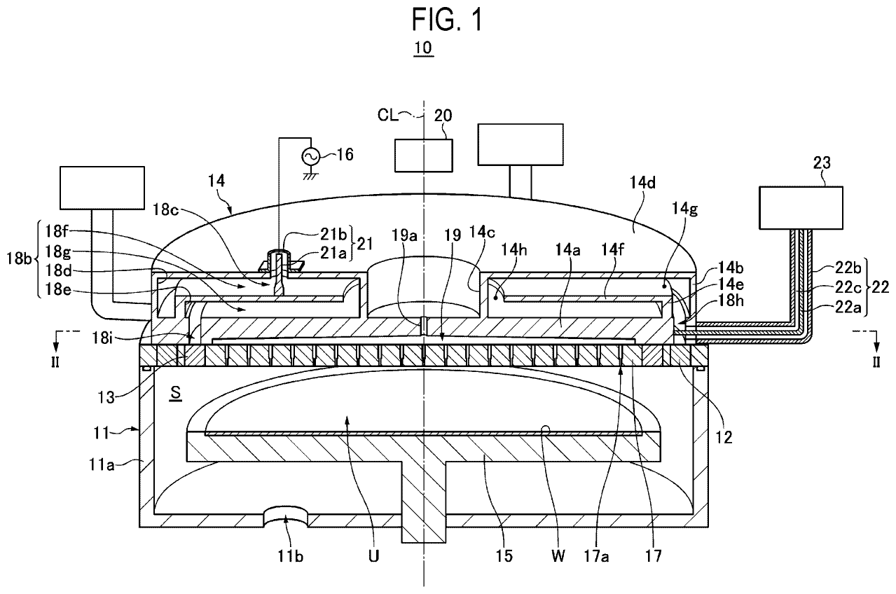

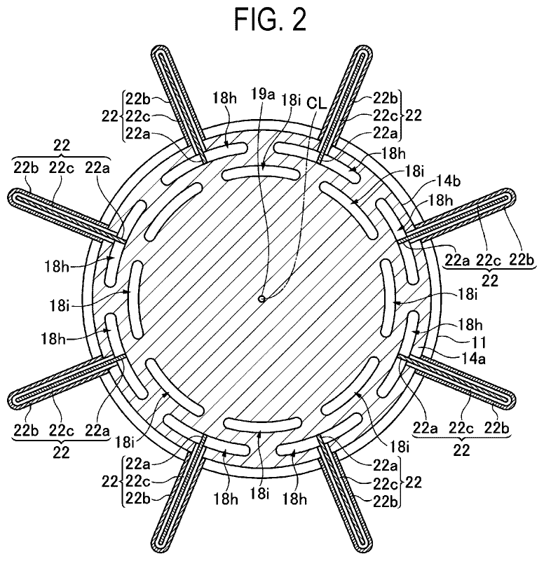

An embodiment of the present disclosure will be described below with reference to the drawings. FIG. 1 is a vertical cross-sectional view schematically illustrating a configuration of a plasma processing apparatus according to an embodiment of the present disclosure, and FIG. 2 is a horizontal cross-sectional view taken along line II-II in FIG. 1.

Referring to FIGS. 1 and 2, the plasma processing apparatus 10 includes a chamber 11 serving as a processing chamber, an outer emitter 12 (first emitter), an inner emitter 13 (second emitter), a waveguide portion 14, a substrate support 15, and a radio-frequency power supply 16.

The chamber 11 is a generally cylindrical container having a central axis CL and a processing space S surrounded by a sidewall 11a. A bottom of the chamber 11 is closed, while a ceiling (top) is open. In the processing space S, a substrate (wafer W) is subjected to plasma processing. The chamber 11 is formed of a metal, such as aluminum, and a corrosion-resistant film is formed on a surface of the chamber 11. The corrosion-resistant film may be a ceramic film, such as an yttrium oxide film, an yttrium oxide fluoride film, an yttrium fluoride film, or a ceramic film containing yttrium oxide or yttrium fluoride. An exhaust port 11b is formed at the bottom of the chamber 11. An exhauster (not shown) is connected to the exhaust port 11b, and the exhauster reduces pressure in the processing space S. The exhauster includes a vacuum pump, such as a dry pump and/or a turbomolecular pump, and an automatic pressure control valve.

An outer emitter 12 and an inner emitter 13 each formed in an annular shape are disposed above the chamber 11. The outer emitter 12 and the inner emitter 13 are disposed so that central axes of the outer emitter 12 and the inner emitter 13 coincide with the central axis CL. The outer emitter 12 and the inner emitter 13 extend along a circumferential direction (hereinafter simply referred to as a “circumferential direction”) around the central axis CL. The inner emitter 13 is disposed closer to the central axis CL, that is, more inward than the outer emitter 12. The outer emitter 12 and the inner emitter 13 are formed of a dielectric material, such as quartz, aluminum nitride, or aluminum oxide, and are configured to emit an electromagnetic wave toward a plasma generation space U in the processing space S as described below.

Above the chamber 11, a shower plate 17 formed in a substantially disk shape is disposed inside the inner emitter 13. Therefore, in the plasma processing apparatus 10, the outer emitter 12, the inner emitter 13, and the shower plate 17 cover an opening formed at the ceiling of the chamber 11, thereby defining a processing space S. The shower plate 17 has a plurality of gas holes 17a penetrating the shower plate 17 in a thickness direction of the shower plate 17. The shower plate 17 is made of a metal, for example, aluminum.

A substrate support 15 is disposed at a lower portion of the processing space S of the chamber 11. The substrate support 15 is a stage on which a wafer W is placed, and is configured to support the placed wafer W in a substantially horizontal posture. The processing space S of the chamber 11 also includes a plasma generation space U. The plasma generation space U exists between the outer emitter 12, the inner emitter 13 and the shower plate 17, and the substrate support 15.

A substantially cylindrical waveguide portion 14 is disposed above the outer emitter 12, the inner emitter 13, and the shower plate 17 so as to cover the outer emitter 12, the inner emitter 13, and the shower plate 17. A gas diffusion space 19 is defined between a thick bottom plate 14a of the waveguide portion 14 and the shower plate 17, and a gas supply 20 is connected to the gas diffusion space 19 via an inlet 19a formed in the waveguide portion 14. Each gas hole 17a connects the gas diffusion space 19 and the processing space S (plasma generation space U). Gas supplied by the gas supply 20 is first diffused in the gas diffusion space 19 and then supplied to the plasma generation space U via each gas hole 17a.

The waveguide portion 14 includes an outer peripheral wall 14b and an inner peripheral wall 14c, both of which are formed in a substantially cylindrical shape. The outer peripheral wall 14b and the inner peripheral wall 14c are disposed so that central axes of the outer peripheral wall 14b and the inner peripheral wall 14c coincide with the central axis CL, and extend along the circumferential direction. The inner peripheral wall 14c is disposed closer to the central axis CL, that is, more inward than the outer peripheral wall 14b. The waveguide portion 14 further includes a plate-shaped ceiling 14d disposed to face the bottom plate 14a. The waveguide portion 14 further includes an intermediate wall 14e formed in a substantially cylindrical shape and disposed between the inner peripheral wall 14c and the outer peripheral wall 14b. The inner peripheral wall 14c, the outer peripheral wall 14b, and the intermediate wall 14e may all be formed by a plurality of columnar bodies arranged along the circumferential direction. The bottom plate 14a, the outer peripheral wall 14b, the inner peripheral wall 14c, and the ceiling 14d are formed of a metal such as an aluminum alloy, copper, nickel, stainless steel, etc. In particular, surfaces of the bottom plate 14a, the outer peripheral wall 14b, the inner peripheral wall 14c, and the ceiling 14d, which are exposed to the waveguide 18b (described later), may be coated with a low-resistance material such as silver, gold, or rhodium.

The waveguide portion 14 includes a resonator 18, which is constituted by a space surrounded by the bottom plate 14a, the outer peripheral wall 14b, the inner peripheral wall 14c, and the ceiling 14d. In this space, the intermediate wall 14e extends upright from the bottom plate 14a but does not reach the ceiling 14d, thereby forming a gap 14g between an upper end of the intermediate wall 14e and the ceiling 14d. Also disposed in this space is a plate-shaped intermediate plate 14f extending substantially horizontally from the upper end of the intermediate wall 14e toward the central axis CL. However, the intermediate plate 14f does not reach the inner peripheral wall 14c, thereby forming a gap 14h between an inner peripheral edge of the intermediate plate 14f and the inner peripheral wall 14c.

The resonator 18 includes a waveguide 18b. The waveguide 18b is a space extending in a radial direction (hereinafter simply referred to as a “radial direction”) around the central axis CL. The waveguide 18b originates from a first end 18d defined by an inner circumferential surface of the outer peripheral wall 14b, passes through the gap 14g, and extends toward the central axis CL along an upper path 18f, which is a space sandwiched between the intermediate plate 14f and the ceiling 14d. Further, the waveguide 18b is folded back at an outer side of the inner peripheral wall 14c, through the gap 14h, toward a lower path 18g, which is a space sandwiched between the intermediate plate 14f and the bottom plate 14a. The waveguide 18b then extends along the lower path 18g toward an opposite side of the central axis CL and reaches a second end 18e defined by an inner circumferential surface of the intermediate wall 14e.

The resonator 18 further includes a coupler 18c. The radio-frequency power supply 16 is connected to the coupler 18c via a coaxial connector 21. The coupler 18c is disposed in the upper path 18f and functions as an entrance to the waveguide 18b for an electromagnetic wave generated based on a radio-frequency power supplied by the radio-frequency power supply 16.

At this time, an inner conductor 21a of the coaxial connector 21 is connected to the intermediate plate 14f, and an outer conductor 21b of the coaxial connector 21 is connected to the ceiling 14d. The radio-frequency power supply 16 may be configured to be capable of changing a frequency of the supplied radio-frequency power.

The resonator 18 further includes a plurality of, for example, eight outer slots 18h (first slots) and a plurality of, for example, eight inner slots 18i (second slots). Respective outer slots 18h are partial grooves extending along the circumferential direction and are formed in the bottom plate 14a below the first end 18d, which is an end of the waveguide 18b. The respective outer slots 18h are evenly spaced apart along the circumferential direction and are interposed between the first end 18d, which is an end of the waveguide 18b, and the outer emitter 12, thereby electromagnetically coupling the waveguide 18b and the outer emitter 12. Respective inner slots 18i are also partial grooves extending along the circumferential direction and are formed in the bottom plate 14a below the second end 18e, which is an end of the waveguide 18b. The respective inner slots 18i are also evenly spaced apart along the circumferential direction and are interposed between the second end 18e, which is an end of the waveguide 18b, and the inner emitter 13, thereby electromagnetically coupling the waveguide 18b and the inner emitter 13. The number of outer slots 18h and inner slots 18i is not limited to eight, and may be two or more as long as they are evenly spaced apart in the circumferential direction.

Furthermore, the inner slots 18i and the outer slots 18h are arranged alternately along the circumferential direction, that is, the inner slots 18i and the outer slots 18h are arranged such that a plurality of radial lines connecting the central axis CL and centers of the respective inner slots 18i and a plurality of radial lines connecting the central axis CL and centers of the respective outer slots 18h are arranged alternately along the circumferential direction.

In the plasma processing apparatus 10, the electromagnetic wave (hereinafter referred to as an “input electromagnetic wave”) introduced into the waveguide 18b from the coupler 18c propagates through the waveguide 18b toward the respective outer slots 18h and the respective inner slots 18i. Furthermore, the electromagnetic wave propagated to the respective outer slots 18h and the respective inner slots 18i is emitted from the outer emitter 12 and the inner emitter 13 into the plasma generation space U. The electromagnetic wave emitted into the plasma generation space U propagates along a lower surface of the shower plate 17 toward a center of the shower plate 17.

In the plasma processing apparatus 10, the gas supplied to the plasma generation space U is excited by an electric field formed by the electromagnetic wave emitted into the plasma generation space U, thereby generating plasma. The electromagnetic wave emitted into the plasma generation space U from the outer emitter 12 and the inner emitter 13 is a radio-frequency wave such as a VHF wave or an UHF wave.

In the plasma processing apparatus 10, a length of the waveguide 18b is set so that a phase of the electromagnetic wave (hereinafter referred to as an “outer emission electromagnetic wave”) emitted from the outer emitter 12 into the plasma generation space U differs from a phase of the electromagnetic wave (hereinafter referred to as an “inner emission electromagnetic wave”) emitted from the inner emitter 13 into the plasma generation space U. For example, the length of the waveguide 18b is set so that the phase of the outer emission electromagnetic wave differs from the phase of the inner emission electromagnetic wave by 180°. Therefore, the outer emission electromagnetic wave and the inner emission electromagnetic wave propagating toward the center of the shower plate 17 interfere with each other and weaken each other. Here, for example, by changing an intensity of the outer emission electromagnetic wave, a degree of interference of the outer emission electromagnetic wave with the inner emission electromagnetic wave can be adjusted, and as a result, a radial electric field intensity in the plasma generation space U, and hence a radial plasma density distribution, can be adjusted.

Here, the intensity of the outer emission electromagnetic wave depends on the magnitude of an impedance of the outer slots 18h. For example, when the impedance of the outer slots 18h is high, the intensity of the outer emission electromagnetic wave increases, and when the impedance of the outer slots 18h is low, the intensity of the outer emission electromagnetic wave decreases. Therefore, in order to change the intensity of the outer emission electromagnetic wave, it is preferable to arrange a mechanism (hereinafter referred to as “impedance varying mechanism”), capable of changing the impedance of the outer slots 18h, corresponding to each outer slot 18h.

However, since each outer slot 18h is located directly above the plasma generation space U, if the impedance varying mechanism were to be arranged near each outer slot 18h, there is a risk of the impedance varying mechanism malfunctioning due to heat input from the plasma generated in the plasma generation space U.

In view of this, in this embodiment, the impedance varying mechanism is positioned away from each outer slot 18h. Specifically, a switch 23 serving as the impedance varying mechanism is connected to each outer slot 18h via a coaxial tube 22.

The coaxial tubes 22 and the switches 23 are evenly spaced apart along the circumferential direction so as to correspond to the plurality of outer slots 18h. Each coaxial tube 22 includes a rod 22a, which is a rod-shaped member made of a conductor, such as metal, and an outer conductor 22b, which is a tubular member made of the same conductor, such as metal. The rod 22a and the outer conductor 22b are disposed coaxially, and the outer conductor 22b surrounds the rod 22a. Therefore, a space 22c exists between the rod 22a and the outer conductor 22b. An input electromagnetic wave reaches the space 22c via the waveguide 18b and then propagates in the space 22c. Each coaxial tube 22 is attached to the waveguide portion 14 so as to correspond to each outer slot 18h, extends outward in the radial direction, and then bends upward. The extension of each coaxial tube 22 is not limited thereto. Furthermore, the switch 23 is attached to an end of each coaxial tube 22 (hereinafter referred to as an “end of the coaxial tube 22”) opposite to the corresponding outer slot 18h (the upper end in FIG. 1.)

In each coaxial tube 22, the rod 22a penetrates the outer peripheral wall 14b of the waveguide portion 14, crosses the corresponding outer slot 18h in the radial direction, and is connected to an inner peripheral side surface of the outer slot 18h. The outer conductor 22b is connected to the outer peripheral wall 14b of the waveguide portion 14. In this embodiment, a portion at which the rod 22a is connected to the inner peripheral side surface of the corresponding outer slot 18h will be hereinafter referred to as a “coaxial tube connection portion”. The switch 23 is connected to an end of the rod 22a opposite to the outer slot 18h. The switch 23 is configured to be capable of switching between short-circuiting the rod 22a to the ground and disconnecting the short-circuit (achieving high impedance.)

As described above, the input electromagnetic wave propagates not only through the waveguide 18b but also through the coaxial tube 22. Therefore, in order to generate a standing wave from the waveguide 18b to the coaxial tube 22 based on the input electromagnetic wave, positions of nodes of the standing wave need to coincide with the position of the second end 18e, which is an end of the waveguide 18b, and the position of a terminal end of the coaxial tube 22. Furthermore, since a wavelength of the standing wave is a wavelength of the input electromagnetic wave, in order to generate a standing wave from the waveguide 18b to the coaxial tube 22, the length of the waveguide (hereinafter referred to as an “entire waveguide”) from the second end 18e, which is the end of the waveguide 18b, to the terminal end of the coaxial tube 22 needs to be set to an integer multiple of a half wavelength of the input electromagnetic wave (n×λ/2, where n is an integer and λ is the wavelength of the input electromagnetic wave). In particular, when the length of the entire waveguide is set to three times the half wavelength of the input electromagnetic wave, a reflection coefficient of the entire waveguide as seen from the coupler 18c becomes low, and the standing wave is reliably generated in the entire waveguide. In other words, when a frequency of the input electromagnetic wave is fixed so that an integer multiple of the half wavelength of the input electromagnetic wave becomes equal to the length of the entire waveguide, the standing wave caused by the input electromagnetic wave is generated in the entire waveguide. In this case, positions of the nodes and antinodes of the standing wave become constant.

On the other hand, from a viewpoint of expanding an adjustment range of the plasma density distribution, it is preferable that when an impedance of the outer slot 18h is set to zero, no electromagnetic wave is emitted from the outer slot 18h, that is, the intensity of the outer emission electromagnetic wave is zero.

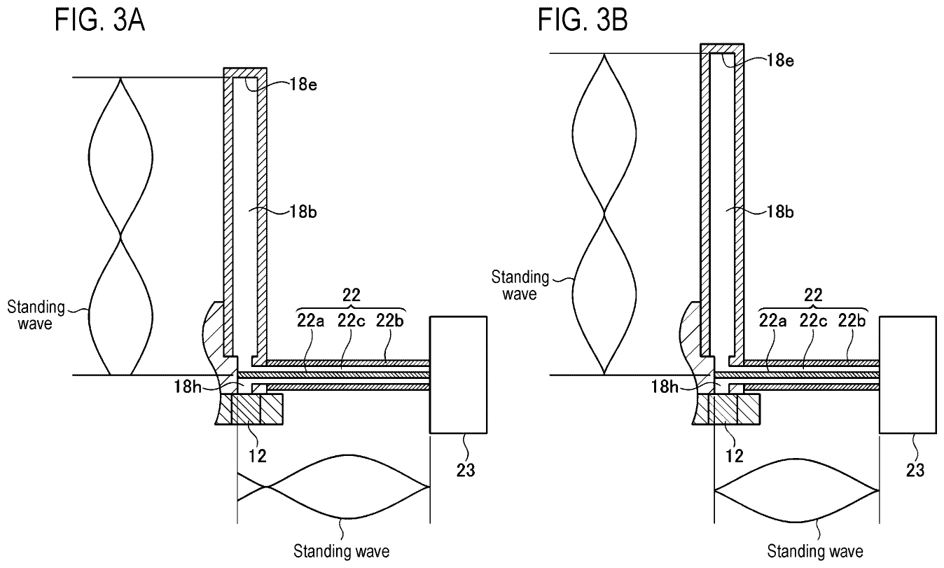

FIGS. 3A and 3B are diagrams illustrating a positional relationship between a node of the standing wave and the coaxial tube connection portion when the standing wave is generated in the entire waveguide. In FIGS. 3A and 3B, in order to easily illustrate the standing wave, the waveguide 18b, which is actually folded back, is shown as extending in a vertical direction, and the coaxial tube 22, which is actually bent, is shown as extending in a horizontal direction. Furthermore, for ease of understanding, the standing wave, which actually exists continuously, is shown separately corresponding to the waveguide 18b and the coaxial tube 22.

First, as shown in FIG. 3A, although a standing wave is generated in the entire waveguide, if a position of the coaxial tube connection portion does not coincide with the positions of nodes of the standing wave, an amplitude of the standing wave will not be zero at the coaxial tube connection portion. Therefore, since the coaxial tube connection portion is connected to the inner peripheral side surface of the outer slot 18h, in practice, the amplitude of the standing wave in the outer slot 18h will not be zero. Furthermore, in the resonator 18, the standing wave in the outer slot 18h is emitted as the outer emission electromagnetic wave from the outer slot 18h into the plasma generation space U. Therefore, if the amplitude of the standing wave in the outer slot 18h is not zero, the intensity of the outer emission electromagnetic wave will not be zero, even if the impedance of the outer slot 18h is set to zero.

Therefore, in this embodiment, the position of the coaxial tube connection portion is adjusted so that the amplitude of the standing wave in the outer slot 18h becomes zero. Specifically, the length of the waveguide from the second end 18e, which is the end of the waveguide 18b, to the position of the coaxial tube connection portion (hereinafter referred to as a “waveguide in the resonator 18”) is set to an integer multiple (n×λ/2) of a half wavelength of the input electromagnetic wave. Alternatively, the frequency of the input electromagnetic wave is set so that an integer multiple of a half wavelength of the input electromagnetic wave becomes equal to a length of the waveguide in the resonator 18. In this case, as shown in FIG. 3B, the position of the coaxial tube connection portion coincides with the position of a node of the standing wave. Therefore, the amplitude of the standing wave at the coaxial tube connection portion becomes zero. Therefore, since the amplitude of the standing wave in the outer slot 18h becomes zero, if the impedance of the outer slot 18h is set to zero, the intensity of the outer emission electromagnetic wave becomes zero.

Even when the position of the coaxial tube connection portion does not coincide with the positions of the nodes of the standing wave as shown in FIG. 3A, the frequency of the input electromagnetic wave may be changed so that an integer multiple of a half wavelength of the input electromagnetic wave becomes equal to the length of the waveguide in the resonator 18. This makes it possible to make the amplitude of the standing wave in the outer slot 18h zero. In this case, however, the length of the waveguide from the coaxial tube connection portion to the end of the coaxial tube 22 (hereinafter referred to as a “waveguide in the coaxial tube 22”) needs to be changed so that the length of the entire waveguide, which is a sum of a length of the waveguide in the coaxial tube 22 and the length of the waveguide in the resonator 18, becomes equal to an integer multiple of a half wavelength of the input electromagnetic wave whose frequency has been changed.

Furthermore, from the viewpoint of expanding the adjustment range of the plasma density distribution, it is preferable that an adjustment range of the intensity of the outer emission electromagnetic wave is large. Therefore, it is preferable that a variation range of the impedance of the outer slot 18h is large. Here, the impedance of the outer slot 18h, that is, an impedance Zᵢₙ of a series circuit of impedances consisting of the coaxial tube 22 and the switch 23 viewed from the coupler 18c, is expressed by the following formula.

$${Z}_{in} = {Z}_{0} \frac{{Z}_{0} + {iZ}_{0} tan β l}{{Z}_{0} + {iZ}_{L} tan β l}$$

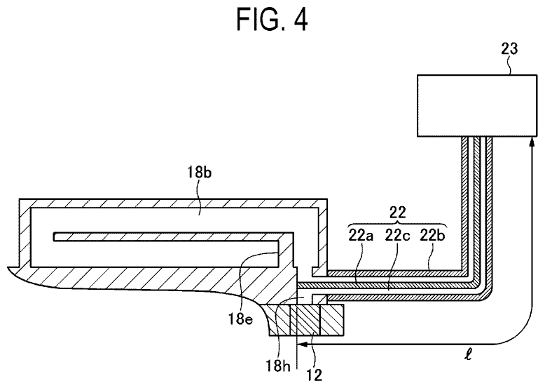

In the above formula, Z₀ is a characteristic impedance of the coaxial tube 22, Z_{L} is an impedance of the switch 23, l is the length of the waveguide in the coaxial tube 22 (see FIG. 4), and β is 2π/λ.

Here, if the length l of the waveguide in the coaxial tube 22 is equal to an odd multiple of a quarter wavelength of the input electromagnetic wave ((2n+1)×λ/4), when a switching state of the switch 23 is set to short-circuiting to the ground so that the impedance Z_{L} becomes zero, the impedance Zᵢₙ of the outer slot 18h becomes infinite. Furthermore, when the switching state of the switch 23 is set to disconnecting the short-circuit so that the impedance Z_{L} becomes infinite, the impedance Zᵢₙ of the outer slot 18h becomes zero. In other words, the variation range of the impedance of the outer slot 18h can be maximized by switching the switch 23.

Further, if the length l of the waveguide in the coaxial tube 22 is equal to an even multiple of a quarter wavelength of the input electromagnetic wave (2n×λ/4), when the switching state of the switch 23 is set to short-circuiting to the ground so that the impedance Z_{L} is zero, the impedance Zᵢₙ of the outer slot 18h becomes zero. When the switching state of the switch 23 is set to disconnecting the short-circuit so that the impedance Z_{L} becomes infinite, the impedance Zᵢₙ of the outer slot 18h becomes infinite. In other words, in this case as well, the variation range of the impedance of the outer slot 18h can be maximized by switching the switch 23.

As described above, in this embodiment, in order to maximize the variation range of the impedance of the outer slot 18h by switching the switch 23, the length of the waveguide in the coaxial tube 22 is set to an odd or even multiple, that is, an integer multiple, of a quarter wavelength of the input electromagnetic wave. Alternatively, the frequency of the input electromagnetic wave is set so that an integer multiple of a quarter wavelength of the input electromagnetic wave becomes equal to the length of the waveguide in the coaxial tube 22. Here, the length of the waveguide in the coaxial tube 22 is equal to a length of the rod 22a.

From the viewpoint of further expanding the adjustment range of the plasma density distribution, it is preferable to set the intensity of the outer emission electromagnetic wave to zero when the impedance Zᵢₙ of the outer slot 18h is set to zero, and to maximize the variation range of the impedance of the outer slot 18h. In order to achieve this, as described above, the length of the waveguide in the resonator 18 needs to be set to an integer multiple of a half wavelength of the input electromagnetic wave, and the length l of the waveguide in the coaxial tube 22 needs to be set to an integer multiple of a quarter wavelength of the input electromagnetic wave. Since an integer multiple of a quarter wavelength of the input electromagnetic wave includes an integer multiple of a half wavelength of the input electromagnetic wave, the requirements above may be rephrased as a requirement that the length of the entire waveguide be set to an integer multiple of a quarter wavelength of the input electromagnetic wave. Therefore, it can be said that, in order to expand the adjustment range of the plasma density distribution, the length of the entire waveguide (the waveguide from the second end 18e, which is the end of the waveguide 18b, to the end of the coaxial tube 22) needs to be set to an integer multiple (at least three times) of a quarter wavelength of the input electromagnetic wave.

In addition, applicant of the present application calculated a distribution of electric field intensity formed in the plasma generation space U by the outer emission electromagnetic wave and the inner emission electromagnetic wave using a simulation model of the plasma processing apparatus 10 in which the switching states of each switch 23 were alternately switched along the circumferential direction.

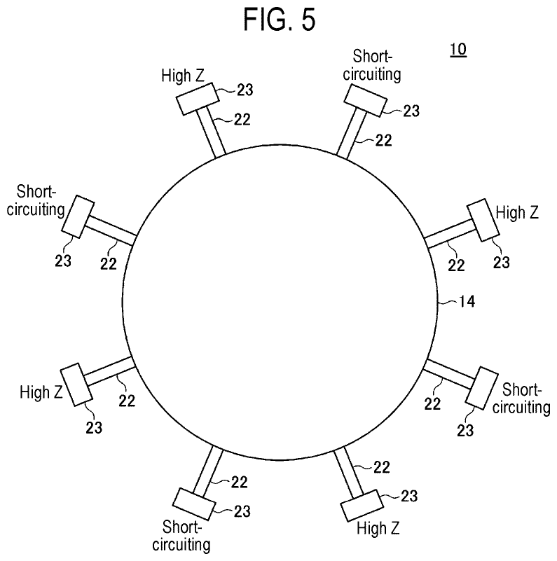

FIG. 5 is a diagram for explaining a simulation model of the plasma processing apparatus 10 used to calculate the plasma density distribution in the plasma generation space U. In FIG. 5, the simulation model of the plasma processing apparatus 10 is shown as viewed from above, and the switching states of the switches 23 are alternately set to either short-circuiting to the ground or disconnecting the short-circuit (achieving high impedance) along the circumferential direction.

In this simulation model, the length of the waveguide in the resonator 18 is set to an integer multiple of a half wavelength of the input electromagnetic wave, and the length of the entire waveguide is set to an integer multiple of a quarter wavelength of the input electromagnetic wave. Furthermore, in this simulation model, eight coaxial tubes 22 are attached to the waveguide portion 14, eight outer slots 18h are provided so as to correspond to the respective coaxial tubes 22, and eight inner slots 18i are also provided. In this simulation model, an outer slot 18h corresponding to a coaxial tube 22 to which a switch 23 set to a switching state of short-circuiting to the ground is attached has an impedance Zᵢₙ of zero. Furthermore, an outer slot 18h corresponding to a coaxial tube 22 to which a switch 23 set to a switching state of disconnecting the short-circuit is attached has an impedance of infinite. In FIG. 5, the short-circuiting to the ground is indicated as “Short-circuiting,” and the disconnecting the short-circuit is indicated as “High Z.”

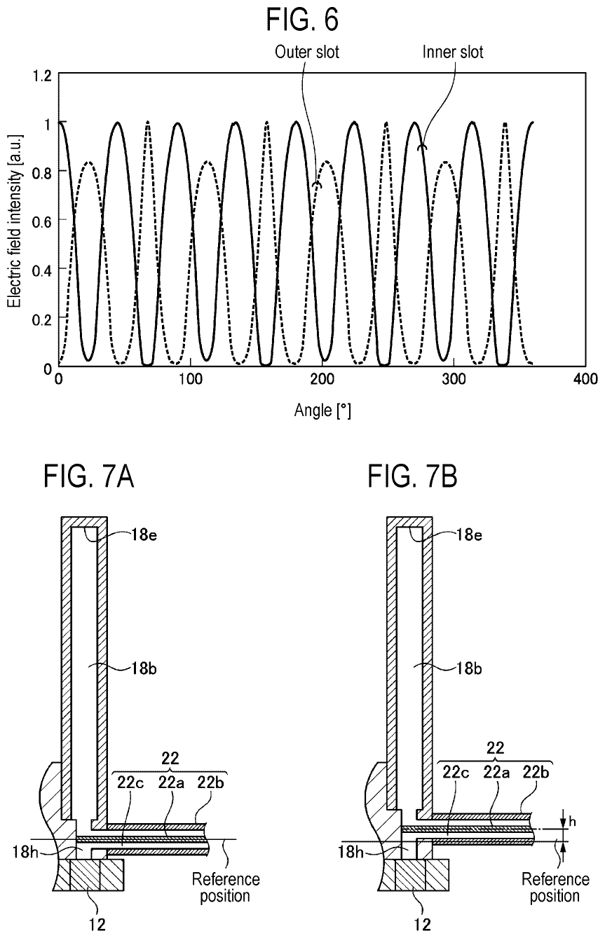

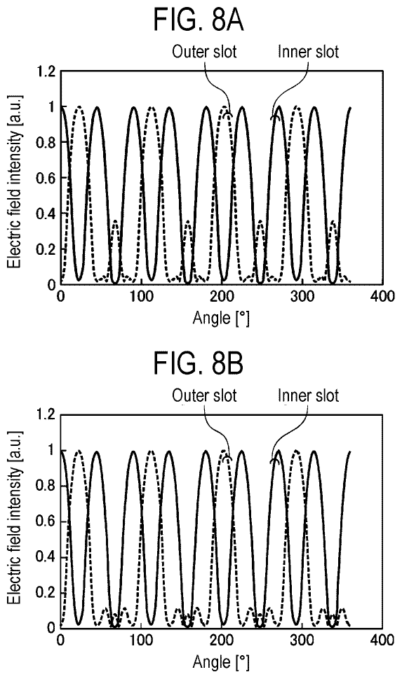

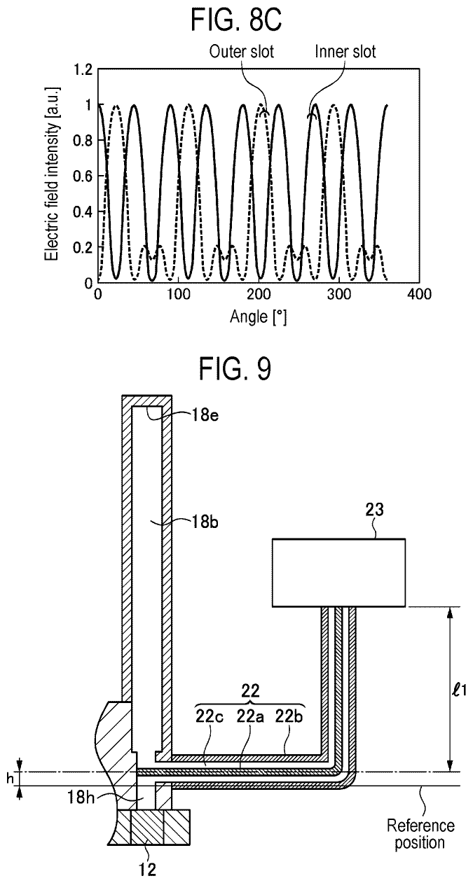

FIG. 6 is a graph showing the distribution of electric field intensity formed in the plasma generation space U calculated using the simulation model of FIG. 5. Angle of a horizontal axis in the graph of FIG. 6 is defined by considering a 3 o'clock direction of FIG. 5 as an origin (0°) and considering a counterclockwise direction in the circumferential direction of FIG. 5 as a positive direction. Hereinafter, angles of horizontal axes in the subsequent graphs showing the distribution of electric field intensity are also defined in the same manner as the angle of the horizontal axis in the graph of FIG. 6. The graph of FIG. 6 shows the distribution of electric field intensity directly below each outer slot 18h and each inner slot 18i in the circumferential direction. In the graph of FIG. 6, positions near 22.5°, 112.5°, 202.5°, and 292.5° in the circumferential direction correspond to positions of the outer slots 18h (impedance Zᵢₙ is infinite) corresponding to the coaxial tubes 22 to which the switches 23 set to a switching state of disconnecting the short-circuit are attached. Furthermore, positions near 67.5°, 157.5°, 247.5°, and 337.5° in the circumferential direction correspond to positions of the outer slots 18h (impedance Zᵢₙ is zero) corresponding to the coaxial tubes 22 to which the switches 23 set to a switching state of short-circuiting to the ground are attached. In the graphs of FIGS. 8A to 8C, 10A to 12B, 18 to 19C described below, circumferential positions of the outer slots 18h are the same as circumferential positions of the outer slots 18h in the graph of FIG. 6.

As shown in FIG. 6, even though the length of the entire waveguide is set to an integer multiple of a quarter wavelength of the input electromagnetic wave, it was confirmed that electromagnetic waves are emitted not only from the outer slots 18h where the impedance Zᵢₙ is infinite, but also from the outer slots 18h where the impedance Zᵢₙ is zero to form an electric field.

Therefore, in order to investigate the reason why electromagnetic waves are emitted from the outer slots 18h where the impedance Zᵢₙ is zero, applicant calculated the distribution of electric field intensity of cases in which the position of the coaxial tube connection portion is moved, using the simulation model of FIG. 5.

FIGS. 7A and 7B are diagrams for explaining a change in the position of the coaxial tube connection portion in the simulation model of FIG. 5. FIG. 7A shows a case in which the position of the coaxial tube connection portion is set to a reference position, and FIG. 7B shows a case in which the position of the coaxial tube connection portion is moved upward by a distance h from the reference position. Using a simulation model in which the position of the coaxial tube connection portion is changed in the vertical direction from the reference position as described above, applicant calculated the distribution of electric field intensity in the plasma generation space U. The distribution of electric field intensity in FIG. 6 corresponds to the distribution of electric field intensity in the case in which the position of the coaxial tube connection portion is set to the reference position.

FIGS. 8A to 8C are graphs showing the distributions of electric field intensity in the plasma generation space U calculated using a simulation model in which the position of the coaxial tube connection portion is changed in the vertical direction. Each graph in FIGS. 8A to 8C also shows the distribution of electric field intensity directly below each outer slot 18h and each inner slot 18i in the circumferential direction. Furthermore, FIG. 8A shows a case in which the position of the coaxial tube connection portion is moved upward by 10 mm from the reference position, FIG. 8B shows a case in which the position of the coaxial tube connection portion is moved upward by 15 mm from the reference position, and FIG. 8C shows a case in which the position of the coaxial tube connection portion is moved upward by 20 mm from the reference position.

As shown in FIGS. 8A to 8C, it was confirmed that when the position of the coaxial tube connection portion is moved upward from the reference position, the electric field intensity directly below the outer slot 18h where the impedance Zᵢₙ is zero tends to decrease. For example, when an amount of upward movement of the coaxial tube connection portion from the reference position changes from 10 mm to 15 mm, it was confirmed that the electric field intensity directly below the outer slot 18h where the impedance Zᵢₙ is zero decreases significantly. However, when the amount of upward movement of the coaxial tube connection portion from the reference position changes from 15 mm to 20 mm, it was confirmed that the electric field intensity directly below the outer slot 18h where the impedance Zᵢₙ is zero increases.

From the above, applicant has found that although the upward movement of the position of the coaxial tube connection portion does not simply decrease the electric field intensity directly below the outer slot 18h where the impedance Zᵢₙ is zero, the electric field intensity directly below the outer slot 18h where the impedance Zᵢₙ is zero can be changed by moving the position of the coaxial tube connection portion. Since the electric field intensity directly below the outer slot 18h where the impedance Zᵢₙ is zero is changed depending on the movement of the position of the coaxial tube connection portion, applicant has found that by optimizing the position of the coaxial tube connection portion, it is possible to reduce the intensity of the electromagnetic wave emitted from the outer slot 18h where the impedance Zᵢₙ is zero.

Furthermore, applicant calculated the distribution of the electric field intensity using the simulation model of FIG. 5 for a case in which not only the position of the coaxial tube connection portion but also the frequency of the input electromagnetic wave and the length of the coaxial tube 22 are changed.

FIG. 9 is a diagram for explaining changes in the position of the coaxial tube connection portion and the length of the coaxial tube 22 in the simulation model of FIG. 5. As shown in FIG. 9, applicant moved the position of the coaxial tube connection portion upward by a distance h from the reference position in the simulation model of FIG. 5, and changed a length l1 from a point of bending to the end of the coaxial tube 22.

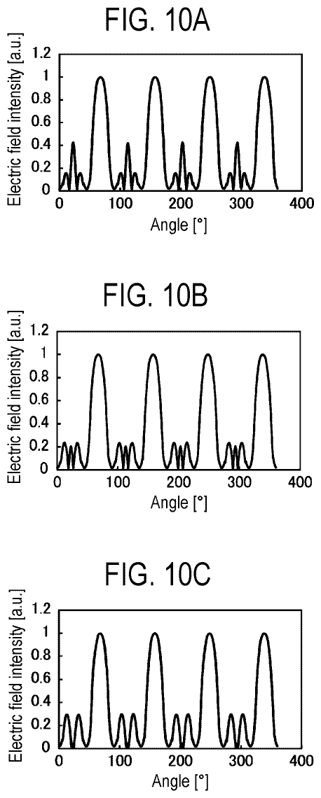

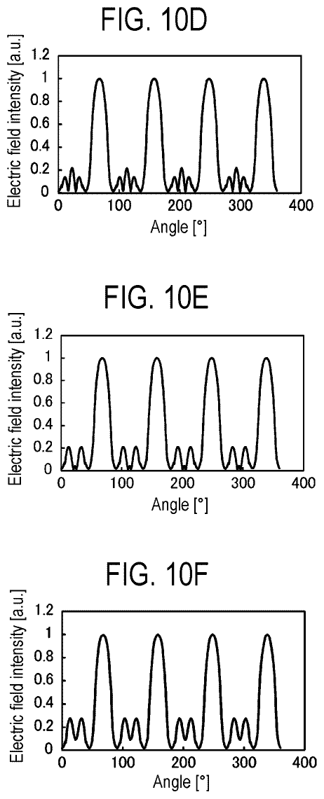

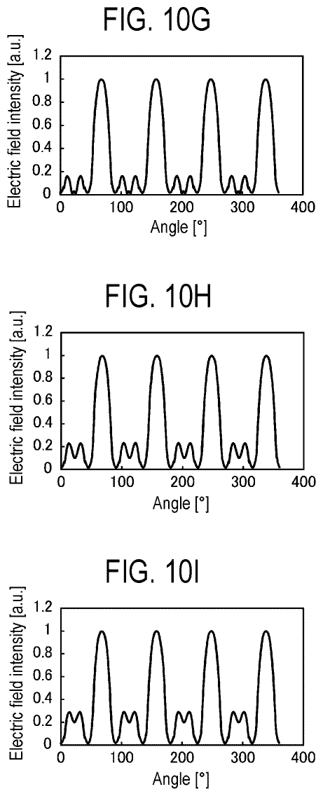

FIGS. 10A to 10I are graphs showing the distributions of electric field intensity in the plasma generation space U calculated using a simulation model in which the position of the coaxial tube connection portion, the frequency of the input electromagnetic wave, and the length of the coaxial tube 22 are changed. Each graph in FIGS. 10A to 10I shows only the distribution of electric field intensity directly below each outer slot 18h in the circumferential direction.

FIG. 10A shows a case in which the position of the coaxial tube connection portion is set to a reference position, the length l1 of the coaxial tube 22 is set to 75 mm, and the frequency of the input electromagnetic wave is set to a reference frequency X. FIG. 10B shows a case in which the position of the coaxial tube connection portion is set to the reference position, the length l1 is set to 80 mm, and the frequency of the input electromagnetic wave is reduced by about 0.16% from the reference frequency X. FIG. 10C shows a case in which the position of the coaxial tube connection portion is set to the reference position, the length l1 is set to 85 mm, and the frequency of the input electromagnetic wave is reduced by about 0.29% from the reference frequency X. FIG. 10D shows a case in which the position of the coaxial tube connection portion is moved upward by 10 mm from the reference position, the length l1 is set to 75 mm, and the frequency of the input electromagnetic wave is increased by about 0.29% from the reference frequency X. FIG. 10E shows a case in which the position of the coaxial tube connection portion is moved upward by 10 mm from the reference position, the length l is set to 80 mm, and the frequency of the input electromagnetic wave is increased by about 0.1% from the reference frequency X. FIG. 10F shows a case in which the position of the coaxial tube connection portion is moved upward by 10 mm from the reference position, the length l is set to 85 mm, and the frequency of the input electromagnetic wave is decreased by about 0.05% from the reference frequency X. FIG. 10G shows a case in which the position of the coaxial tube connection portion is moved upward by 20 mm from the reference position, the length l is set to 75 mm, and the frequency of the input electromagnetic wave is increased by about 0.65% from the reference frequency X. FIG. 10H shows a case in which the position of the coaxial tube connection portion is moved upward by 20 mm from the reference position, the length l is set to 80 mm, and the frequency of the input electromagnetic wave is increased by about 0.44% from the reference frequency X. FIG. 10I shows a case in which the position of the coaxial tube connection portion is moved upward by 20 mm from the reference position, the length l is set to 85 mm, and the frequency of the input electromagnetic wave is increased by about 0.29% from the reference frequency X.

From the graphs of FIGS. 10A to 10I, it can be noted that when the position of the coaxial tube connection portion is set to the reference position, if the length l1 is set to 80 mm and the frequency of the input electromagnetic wave is reduced by about 0.16% from the reference frequency X (FIG. 10B), the electric field intensity directly below the outer slot 18h where the impedance Zᵢₙ is zero is the lowest. Furthermore, it can be noted that when the position of the coaxial tube connection portion is moved upward by 10 mm from the reference position, if the length l1 is set to 75 mm and the frequency of the input electromagnetic wave is increased by about 0.29% from the reference frequency X (FIG. 10D), the electric field intensity directly below the outer slot 18h where the impedance Zᵢₙ is zero is the lowest. In addition, it can be noted that when the position of the coaxial tube connection portion is moved upward by 20 mm from the reference position, if the length l1 is set to 75 mm and the frequency of the input electromagnetic wave is increased by about 0.65% from the reference frequency X (FIG. 10G), the electric field intensity directly below the outer slot 18h where the impedance Zᵢₙ is zero is the lowest.

From the above, applicant has found that by changing the position of the coaxial tube connection portion, the frequency of the input electromagnetic wave, and the length of the coaxial tube 22, it is possible to reduce the electric field intensity directly below the outer slot 18h where the impedance Zᵢₙ is zero.

From the results shown in FIGS. 10B, 10D and 10G, applicant has found that when the electric field intensity directly below the outer slot 18h where the impedance Zᵢₙ is zero is reduced, if the position of the coaxial tube connection portion is moved upward, the frequency of the input electromagnetic wave needs to be increased. Here, moving the position of the coaxial tube connection portion upward means shortening the waveguide in the resonator 18. Therefore, it can also be said that when reducing the electric field intensity directly below the outer slot 18h where the impedance Zᵢₙ is zero, that is, the intensity of the outer emission electromagnetic wave, if the waveguide in the resonator 18 is shortened, the frequency of the input electromagnetic wave needs to be increased.

On the other hand, as described above, in order to make the intensity of the outer emission electromagnetic wave to be zero when the impedance of the outer slot 18h is set to zero, the length of the waveguide in the resonator 18 needs to be set to an integer multiple of a half wavelength of the input electromagnetic wave. Therefore, in order to make the intensity of the outer emission electromagnetic wave zero, when the waveguide in the resonator 18 is shortened, the wavelength of the input electromagnetic wave needs to be shortened, that is, the frequency of the input electromagnetic wave needs to be increased. This requirement is consistent with the finding obtained from the results shown in FIGS. 10B, 10D and 10G that when reducing the intensity of the outer emission electromagnetic wave, if the waveguide in the resonator 18 is shortened, the frequency of the input electromagnetic wave needs to be increased.

Furthermore, applicant changed the reference frequency and calculated the distribution of electric field intensity using the simulation model of FIG. 5 for cases in which the position of the coaxial tube connection portion, the frequency of the input electromagnetic wave, and the length of the coaxial tube 22 are changed, in order to find an allowable amount of movement of the position of the coaxial tube connection portion.

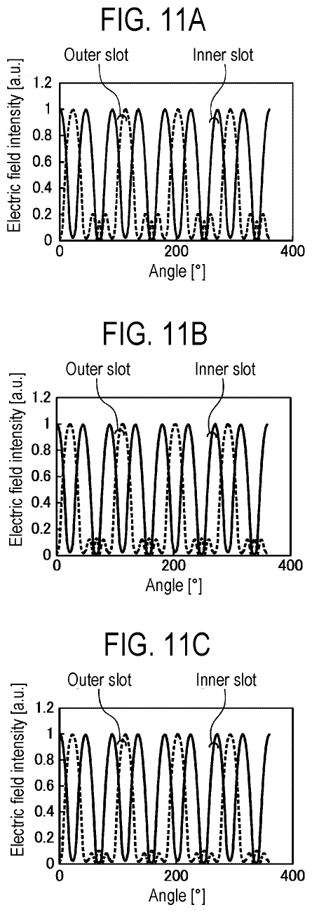

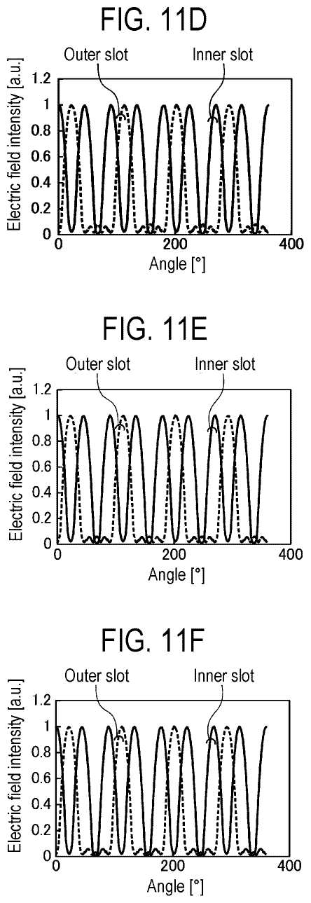

FIGS. 11A to 11F are graphs showing the distributions of electric field intensity in the plasma generation space U calculated using a simulation model in which the position of the coaxial tube connection portion, the frequency of the input electromagnetic wave, and the length of the coaxial tube 22 are changed. Each graph in FIGS. 11A to 11F shows the distribution of electric field intensity directly below each outer slot 18h and each inner slot 18i in the circumferential direction. In addition, a reference frequency Z used in calculating the results shown in FIGS. 11A to 11F is different from the reference frequency X used in calculating the results shown in FIGS. 10A to 10I.

FIG. 11A shows a case in which the position of the coaxial tube connection portion is set to the reference position, the length l1 is set to 257 mm, and the frequency of the input electromagnetic wave is reduced by about 1.36% from the reference frequency Z. FIG. 11B shows a case in which the position of the coaxial tube connection portion is moved upward by 10 mm from the reference position, the length l1 is set to 253 mm, and the frequency of the input electromagnetic wave is reduced by about 1.05% from the reference frequency Z. FIG. 11C shows a case in which the position of the coaxial tube connection portion is moved upward by 20 mm from the reference position, the length l1 is set to 249 mm, and the frequency of the input electromagnetic wave is reduced by about 0.60% from the reference frequency Z. FIG. 11D shows a case in which the position of the coaxial tube connection portion is moved upward by 30 mm from the reference position, the length l1 is set to 245 mm, and the frequency of the input electromagnetic wave is set to the reference frequency Z. FIG. 11E shows a case in which the position of the coaxial tube connection portion is moved upward by 40 mm from the reference position, the length l1 is set to 241 mm, and the frequency of the input electromagnetic wave is increased by about 0.74% from the reference frequency Z. FIG. 11F shows a case in which the position of the coaxial tube connection portion is moved upward by 50 mm from the reference position, the length l1 is set to 237 mm, and the frequency of the input electromagnetic wave is increased by about 1.60% from the reference frequency Z.

From the graphs shown in FIGS. 11A to 11F, it was confirmed that, in the results shown in FIGS. 11B to 11E, even if the frequency of the input electromagnetic wave fluctuates within a range of approximately +1% from the reference frequency Z, the electric field intensity directly below the outer slot 18h where the impedance Zᵢₙ is zero decreases.

In the calculations of the distribution of electric filed intensity corresponding to FIGS. 11B to 11E, the position of the coaxial tube connection portion moved approximately 30 mm (±15 mm) in the vertical direction. This amount of movement corresponds to ±1/40 of the wavelength of the input electromagnetic wave of the reference frequency Z (±λ/40). In other words, applicant has found that when the frequency of the input electromagnetic wave fluctuates within the range of approximately ±1% from the reference frequency Z, even when the position of the coaxial tube connection portion moves within a range of ±n×λ/80 of the wavelength of the input electromagnetic wave of the reference frequency Z (an integer multiple of ±1/80), the electric field intensity directly below the outer slot 18h where the impedance Zᵢₙ is zero can be reduced.

Furthermore, in order to confirm the above findings, applicant further changed the reference frequency and calculated the distribution of the electric field intensity using the simulation model of FIG. 5 for a case in which the position of the coaxial tube connection portion and the frequency of the input electromagnetic wave are changed.

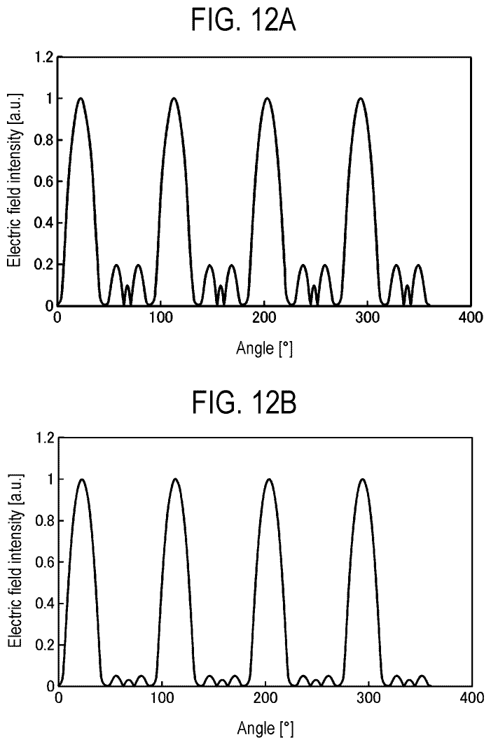

FIGS. 12A and 12B are graphs showing the distribution of electric field intensity in the plasma generation space U calculated using a simulation model in which the position of the coaxial tube connection portion and the frequency of the input electromagnetic wave are changed. Each graph in FIGS. 12A and 12B shows only the distribution of electric field intensity directly below each outer slot 18h in the circumferential direction. Furthermore, the reference frequency Y used in calculating the results shown in FIGS. 12A and 12B is different from the reference frequency X used in calculating the results shown in FIGS. 10A to 10I and the reference frequency Z used in calculating the results shown in FIGS. 11A to 11F.

FIG. 12A shows a case in which the position of the coaxial tube connection portion is set to the reference position and the frequency of the input electromagnetic wave is set to the reference frequency Y. FIG. 12B shows a case in which the position of the coaxial tube connection portion is moved upward by 34 mm from the reference position and the frequency of the input electromagnetic wave is increased by about 1.09% from the reference frequency Y.

From the graphs shown in FIGS. 12A and 12B, it was confirmed that the electric field intensity directly below the outer slot 18h where the impedance Zᵢₙ is zero decreases even when the frequency of the input electromagnetic wave varies by approximately 1.1% from the reference frequency Y. Here, the amount of movement of the position of the coaxial tube connection portion, 34 mm, corresponds to 1/40 of the wavelength of the input electromagnetic wave of the reference frequency Y (λ/40). This result is consistent with the finding obtained from the results shown in FIGS. 11B to 11E that the electric field intensity directly below the outer slot 18h where the impedance Zᵢₙ is zero can be reduced even when the position of the coaxial tube connection portion is moved within a range of an integer multiple of ±1/80 of the wavelength of the input electromagnetic wave of the reference frequency (±n×λ/80).

According to this embodiment, the switch 23 is connected to the end of the rod 22a which is connected to the inner peripheral side surface of the outer slot 18h. The switch 23 is configured to be capable of switching between short-circuiting to the ground and disconnecting the short-circuit. This makes it possible to change the impedance of the outer slots 18h, and in turn, to change the electric field intensity, that is, the intensity of the outer emission electromagnetic wave, directly below the outer slots 18h where the impedance Zᵢₙ is zero.

Furthermore, in this embodiment, since the length of the waveguide in the resonator 18 is set to an integer multiple of a half wavelength of the input electromagnetic wave, the position of the coaxial tube connection portion can coincide with the positions of the nodes of the standing wave generated in the entire waveguide, and the amplitude of the standing wave in the outer slot 18h can become nearly zero. As a result, when the impedance of the outer slot 18h is set to zero, the intensity of the outer emission electromagnetic wave can become nearly zero.

Furthermore, in this embodiment, the length l of the waveguide in the coaxial tube 22 is set to an integer multiple of a quarter wavelength of the input electromagnetic wave. Therefore, the variation range in impedance of the outer slot 18h due to the switching of the switch 23 can be maximized, and the adjustment range for the intensity of the outer emission electromagnetic wave can be expanded.

As described above, in the plasma processing apparatus 10, the adjustment range for the plasma density distribution in the plasma generation space U of the chamber 11 can be expanded, thereby improving a controllability of the plasma density distribution in the plasma generation space U.

Furthermore, in this embodiment, since the switches 23 are connected to the outer slots 18h via the coaxial tubes 22, the switches 23 are spaced apart from the outer slots 18h and are not affected by the heat input from the plasma generated in the plasma generation space U. As a result, malfunctions of the switches 23 caused by heat can be prevented, and a reliability of the plasma processing apparatus 10 can be improved.

Although the preferred embodiment of the present disclosure has been described above, the present disclosure is not limited to the above-described embodiment, and various modifications and changes may be made within the scope of the gist of the present disclosure.

For example, in this embodiment, the switch 23 configured to be capable of switching between short-circuiting to the ground and disconnecting the short-circuit is used as the impedance varying mechanism. However, a gradual impedance varying mechanism that can gradually change the impedance may also be used as the impedance varying mechanism.

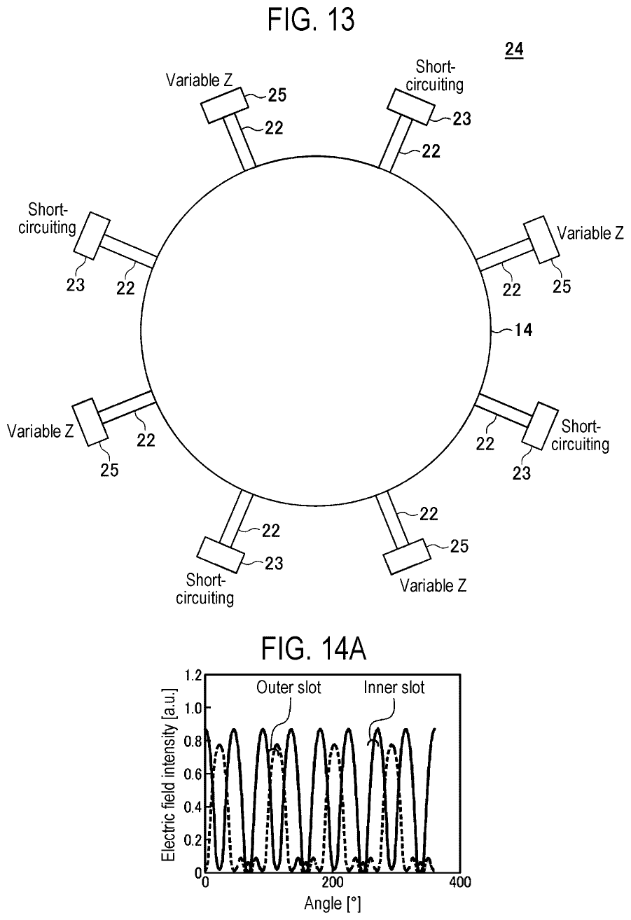

FIG. 13 is a diagram illustrating a configuration of a first modification of the plasma processing apparatus 10. FIG. 13 shows a simplified diagram of a plasma processing apparatus 24, which is the first modification of the plasma processing apparatus 10, as viewed from above. In the plasma processing apparatus 24, gradual impedance varying mechanisms 25 are attached to ends of some of the coaxial tubes 22 instead of the switches 23. Specifically, the switches 23 and the gradual impedance varying mechanisms 25 are attached alternately to the respective coaxial tubes 22 in the circumferential direction.

Applicant also created a simulation model of the plasma processing apparatus 24 which has the same configuration as the simulation model of FIG. 5, except that the switches 23 and the gradual impedance varying mechanisms 25 are attached alternately to the respective coaxial tubes 22 in the circumferential direction. Using the simulation model of the plasma processing apparatus 24, applicant calculated the distribution of electric field intensity in the plasma generation space U when an impedance of each gradual impedance varying mechanism 25 is changed. In the simulation model of the plasma processing apparatus 24, the switching states of all the switches 23 were set to short-circuiting. Further, in the simulation model of the plasma processing apparatus 24, the frequency of the input electromagnetic wave was optimized so that a standing wave is generated in the entire waveguide when the impedance of each gradual impedance changing mechanism 25 is changed.

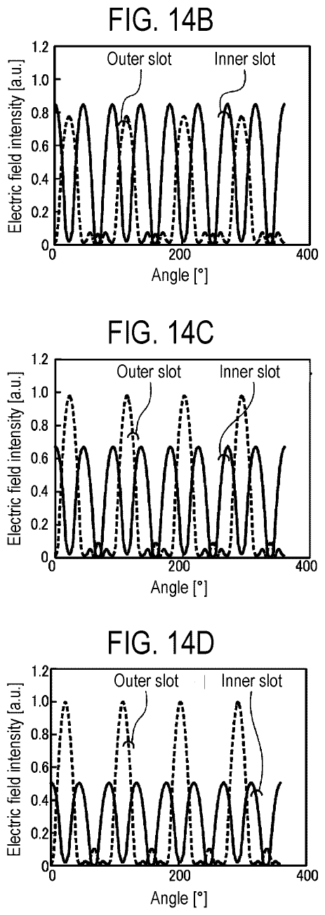

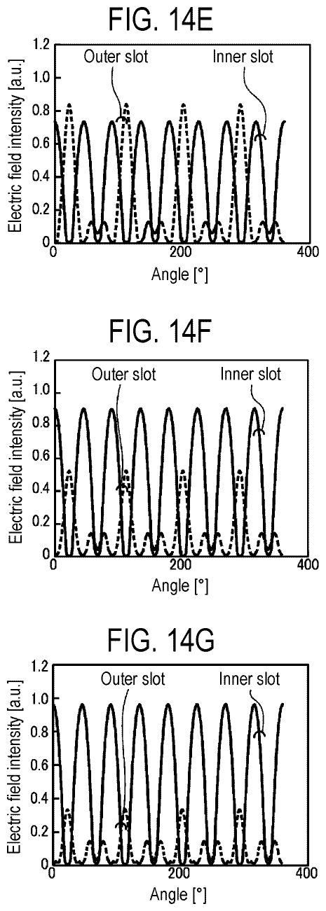

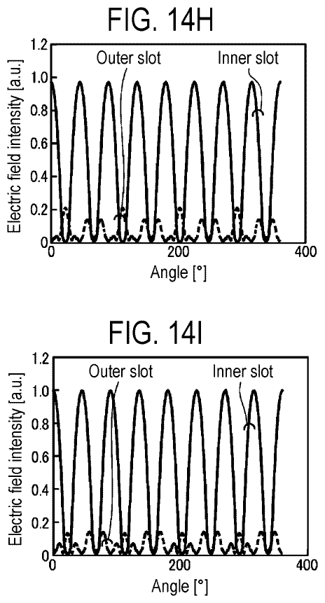

FIGS. 14A to 14I are graphs showing the distribution of electric field intensity in the plasma generation space U calculated using a simulation model of the plasma processing apparatus 24 in which the impedance of each gradual impedance varying mechanism 25 is changed. Each graph in FIGS. 14A to 14I also shows the distribution of electric field intensity directly below each outer slot 18h and each inner slot 18i in the circumferential direction. In each graph in FIGS. 14A to 14I, positions near 22.5°, 112.5°, 202.5°, and 292.5° in the circumferential direction correspond to positions of the outer slots 18h corresponding to the coaxial tubes 22 to which the gradual impedance varying mechanisms 25 are attached. In addition, positions near 67.5°, 157.5°, 247.5°, and 337.5° in the circumferential direction correspond to positions of the outer slots 18h corresponding to the coaxial tubes 22 to which the switches 23 are attached.

FIG. 14A shows a case in which the short-circuit is disconnected (high impedance is achieved) in each gradual impedance varying mechanism 25, FIG. 14B shows a case in which the impedance of each gradual impedance varying mechanism 25 is set to 100 ohms, FIG. 14C shows a case in which the impedance of each gradual impedance varying mechanism 25 is set to 33 ohms, FIG. 14D shows a case in which the impedance of each gradual impedance varying mechanism 25 is set to 22 ohms, FIG. 14E shows a case in which the impedance of each gradual impedance varying mechanism 25 is set to 10 ohms, FIG. 14F shows a case in which the impedance of each gradual impedance varying mechanism 25 is set to 6.8 ohms, FIG. 14G shows a case in which the impedance of each gradual impedance varying mechanism 25 is set to 4.7 ohms, FIG. 14H shows a case in which the impedance of each gradual impedance varying mechanism 25 is set to 3.3 ohms, and FIG. 14I shows a case in which the impedance of each gradual impedance varying mechanism 25 is set to 2.2 ohms.

As shown in the graphs of FIGS. 14A to 14I, when the impedance of each gradual impedance varying mechanism 25 is gradually changed from high impedance to low impedance, it was confirmed that, at first, the electric field intensity directly below the outer slots 18h corresponding to the coaxial tubes 22 to which the gradual impedance varying mechanism 25 is attached increases while the electric field intensity directly below all the inner slots 18i decreases. However, as the impedance of each gradual impedance varying mechanism 25 is further decreased, from a point at which the impedance of each gradual impedance changing mechanism 25 is set to 22Ω (FIG. 14D), it was confirmed that the electric field intensity directly below the inner slots 18i increases while the electric field intensity directly below the outer slots 18h corresponding to the coaxial tubes 22 decreases overall.

From the above, applicant has found that it is possible to totally reverse the electric field intensity directly below the inner slots 18i and the electric field intensity directly below the outer slots 18h by changing the impedance of each gradual impedance varying mechanism 25. Based on this finding, applicant has concluded that, by rapidly changing the impedance of each gradual impedance varying mechanism 25, balancing the electric field intensity directly below the inner slots 18i and the electric field intensity directly below the outer slots 18h with a time average, and thereby achieving uniform plasma density distribution in the radial and circumferential directions in the plasma generation space U is possible.

Furthermore, applicant has concluded that, by adjusting the impedance of each gradual impedance varying mechanism 25, finely adjusting the impedance of the outer slot 18h corresponding to the coaxial tube 22 to which the gradual impedance varying mechanism 25 is attached is possible, which enables precise adjustment of the electric field intensity directly below the outer slot 18h corresponding to the coaxial tube 22, and ultimately precise adjustment of the radial and circumferential plasma density distribution in the plasma generation space U.

As shown in the graphs of FIGS. 14A to 14I, it was also confirmed that even when the impedance of each gradual impedance varying mechanism 25 is changed, the electric field intensity directly below each outer slot 18h where the switching state of the corresponding switch 23 is set to short-circuiting so that the impedance is zero is very low, that is, electromagnetic wave is hardly emitted from each outer slot 18h where the switching state of the corresponding switch 23 is set to short-circuiting so that the impedance is zero.

Furthermore, instead of alternately attaching the switches 23 and the gradual impedance varying mechanisms 25 to the respective coaxial tubes 22, the gradual impedance varying mechanisms may be attached to all the coaxial tubes 22.

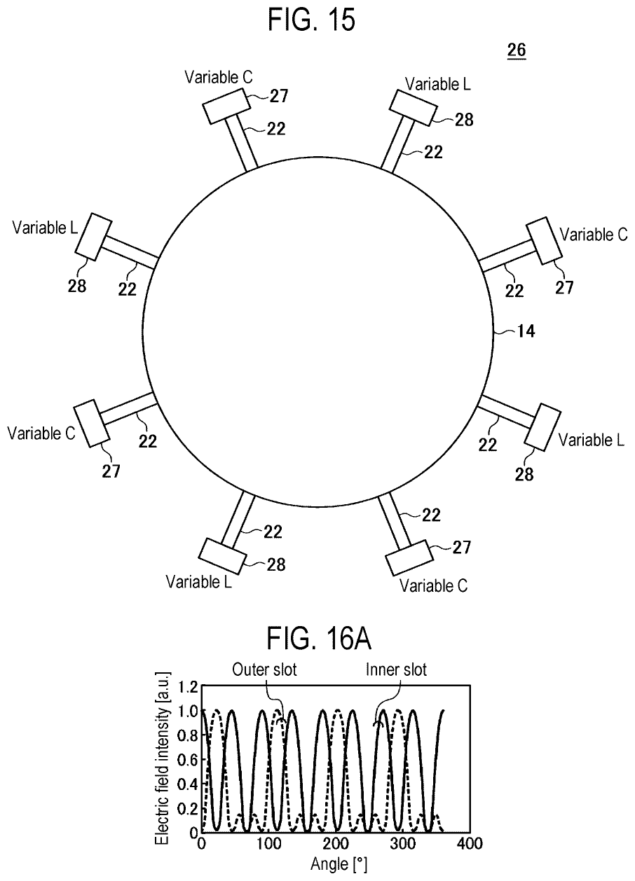

FIG. 15 is a diagram for explaining the configuration of a second modification of the plasma processing apparatus 10. FIG. 15 shows a simplified diagram of a plasma processing apparatus 26, which is the second modification of the plasma processing apparatus 10, as viewed from above. In the plasma processing apparatus 26, variable capacitor mechanisms 27 capable of gradually changing a capacitance of a capacitor and variable inductor mechanisms 28 capable of gradually changing an inductance are used as the gradual impedance varying mechanisms. Specifically, in the plasma processing apparatus 26, the variable capacitor mechanisms 27 and the variable inductor mechanisms 28 are attached alternately to the respective coaxial tubes 22 in the circumferential direction.

Here, applicant created a simulation model of the plasma processing apparatus 26 which has the same configuration as the simulation model of FIG. 5, except that the variable capacitor mechanisms 27 and the variable inductor mechanisms 28 are attached alternately to the respective coaxial tubes 22 in the circumferential direction. Then, using the simulation model of the plasma processing apparatus 26, applicant calculated the distribution of electric field intensity in the plasma generation space U when the capacitance of each variable capacitor mechanism 27 and the inductance of each variable inductor mechanism 28 are changed. In the simulation model of the plasma processing apparatus 26, the frequency of the input electromagnetic wave was optimized so that a standing wave is generated in the entire waveguide when the capacitance of each variable capacitor mechanism 27 and the inductance of each variable inductor mechanism 28 are changed.

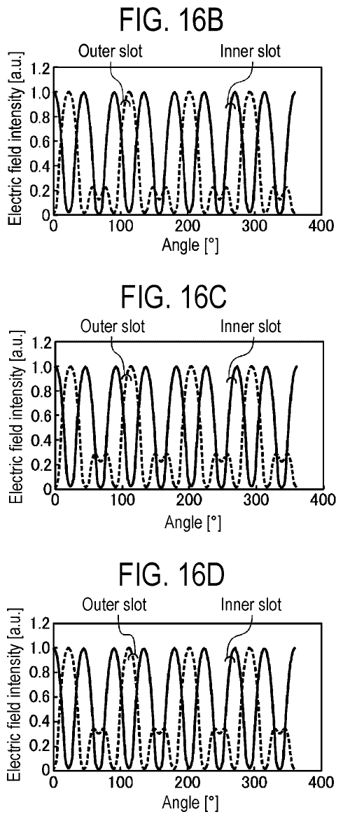

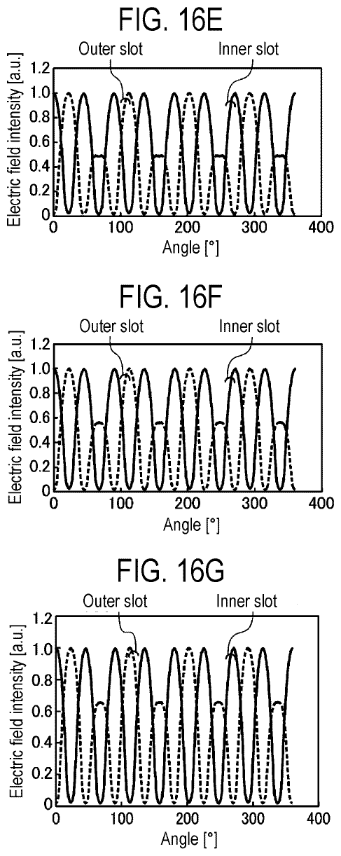

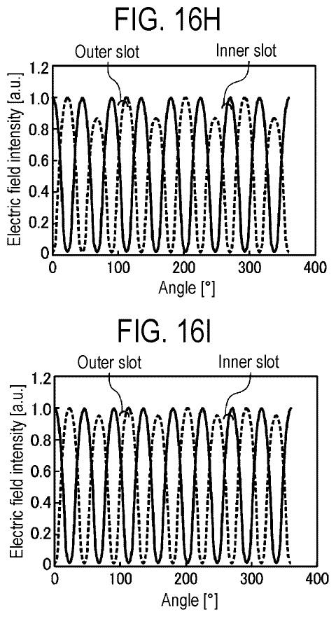

FIGS. 16A to 16I are graphs showing the distribution of electric field intensity in the plasma generation space U calculated using a simulation model of the plasma processing apparatus 26 in which the capacitance of each variable capacitor mechanism 27 and the inductance of each variable inductor mechanism 28 are changed. Each graph in FIGS. 16A to 16I also shows the distributions of electric field intensity directly below each outer slot 18h and each inner slot 18i in the circumferential direction. In each graph in FIGS. 16A to 16I, positions near 22.5°, 112.5°, 202.5°, and 292.5° in the circumferential direction correspond to positions of the outer slots 18h corresponding to the coaxial tubes 22 to which the variable capacitor mechanisms 27 are attached. In addition, positions near 67.5°, 157.5°, 247.5°, and 337.5° in the circumferential direction correspond to positions of the outer slots 18h corresponding to the coaxial tubes 22 to which the variable inductor mechanisms 28 are attached.

FIG. 16A shows a case in which the capacitance of each variable capacitor mechanism 27 is set to 130 fF and the inductance of each variable inductor mechanism 28 is set to 0.33 nH. FIG. 16B shows a case in which the capacitance of each variable capacitor mechanism 27 is set to 464 fF and the inductance of each variable inductor mechanism 28 is set to 1.16 nH. FIG. 16C shows a case in which the capacitance of each variable capacitor mechanism 27 is set to 800 fF and the inductance of each variable inductor mechanism 28 is set to 2 nH. FIG. 16D shows a case in which the capacitance of each variable capacitor mechanism 27 is set to 1.14 pF and the inductance of each variable inductor mechanism 28 is set to 2.85 nH. FIG. 16E shows a case in which the capacitance of each variable capacitor mechanism 27 is set to 2.57 pF and the inductance of each variable inductor mechanism 28 is set to 6.43 nH. FIG. 16F shows a case in which the capacitance of each variable capacitor mechanism 27 is set to 4.23 pF and the inductance of each variable inductor mechanism 28 is set to 10.6 nH. FIG. 16G shows a case in which the capacitance of each variable capacitor mechanism 27 is set to 63.8 fF and the inductance of each variable inductor mechanism 28 is set to 10 nH. FIG. 16H shows a case in which the capacitance of each variable capacitor mechanism 27 is set to 63.8 fF and the inductance of each variable inductor mechanism 28 is set to 33 nH. FIG. 16I shows a case in which the capacitance of each variable capacitor mechanism 27 is set to 63.8 fF and the inductance of each variable inductor mechanism 28 is set to 100 nH.

As shown in the graphs of FIGS. 16A to 16I, it was confirmed that, in the outer slot 18h corresponding to the coaxial tube 22 to which the variable capacitor mechanism 27 with a small capacitance is attached, since the impedance Zᵢₙ of the outer slot 18h becomes high, the intensity of the outer emission electromagnetic wave becomes high and the electric field intensity directly below the outer slot 18h increases. Furthermore, it was confirmed that, in the outer slot 18h corresponding to the coaxial tube 22 to which the variable inductor mechanism 28 with a low inductance is attached, since the impedance Zᵢₙ of the outer slot 18h becomes low, the intensity of the outer emission electromagnetic wave becomes low and the electric field intensity directly below the outer slot 18h decreases.

As shown in the graphs of FIGS. 16A to 16F, when the capacitance of each variable capacitor mechanism 27 is gradually increased and the inductance of each variable inductor mechanism 28 is gradually increased, the impedance Zᵢₙ of the outer slot 18h corresponding to the coaxial tube 22 to which the variable inductor mechanism 28 is attached gradually increases, and therefore the electric field intensity directly below the outer slot 18h increases. On the other hand, it was also confirmed that, although the impedance Zᵢₙ of the outer slot 18h corresponding to the coaxial tube 22 to which the variable capacitor mechanism 27 is attached gradually decreases, the electric field intensity directly below the outer slot 18h remains almost unchanged.

From the above, applicant has found that it is possible to adjust the distribution of electric field intensity in the circumferential direction by changing the capacitance of each variable capacitor mechanism 27 and the inductance of each variable inductor mechanism 28. In particular, it has been found that by individually adjusting the capacitance of each variable capacitor mechanism 27 and the inductance of each variable inductor mechanism 28, it is possible to individually adjust the intensity of the outer emission electromagnetic wave in each outer slot 18h, thereby enabling more precise adjustment of the distribution of electric field intensity in the circumferential direction.

Furthermore, as shown in the graphs of FIGS. 16A to 16F, applicant has also found that even when the capacitance of each variable capacitor mechanism 27 is increased so that the impedance Zᵢₙ of the corresponding outer slot 18h is reduced, when the inductance of each variable inductor mechanism 28 is increased, the intensity of the outer emission electromagnetic waves in the outer slot 18h corresponding to the variable capacitor mechanism 27 does not decrease. Therefore, even when the impedance Zᵢₙ of a certain outer slot 18h is reduced, when the impedance Zᵢₙ of the adjacent outer slot 18h is increased, a level of emission of the outer emission electromagnetic wave from the outer slot 18h of which the impedance Zᵢₙ has been reduced can be maintained.

When the switch 23 is attached to the coaxial tube 22, in order to increase the variation range of the impedance of the corresponding outer slot 18h, it was necessary to set the length l of the waveguide in the coaxial tube 22 to an odd multiple of a quarter wavelength of the input electromagnetic wave. However, when the gradual impedance varying mechanism 25, the variable capacitor mechanism 27, or the variable inductor mechanism 28 is attached to the coaxial tube 22, the variation range of the impedance of the corresponding outer slot 18h can be increased by finely adjusting the capacitance or inductance of the gradual impedance varying mechanism 25, the variable capacitor mechanism 27, or the variable inductor mechanism 28. Therefore, it is not always necessary to set the length l of the waveguide in the coaxial tube 22 to an odd multiple of a quarter wavelength of the input electromagnetic wave.

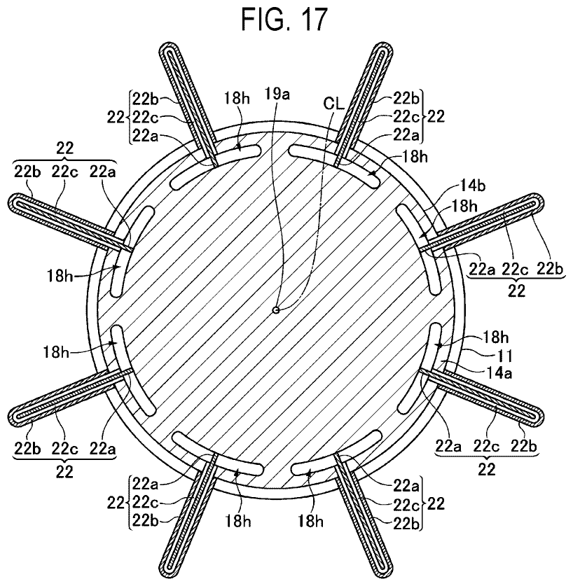

In the plasma processing apparatus 10, the resonator 18 includes the plurality of outer slots 18h but also the plurality of inner slots 18i. However, the resonator 18 may not include the plurality of inner slots 18i (FIG. 17). In this case, in a plasma processing apparatus (third modification) including only the plurality of outer slots 18h, an electromagnetic wave (outer emission electromagnetic wave) emitted from each outer slot 18h (each outer emitter 12) into the plasma generation space U propagate along the lower surface of the shower plate 17. In the third modification, the respective outer slots 18h are also disposed along the circumferential direction. Therefore, when the intensity of the outer emission electromagnetic wave is changed, it is possible to adjust the circumferential electric field intensity in the plasma generating space U, and hence the circumferential plasma density distribution.

Applicant also calculated the distribution of electric field intensity formed in the plasma generation space U by the outer emission electromagnetic wave using a simulation model of the third modification which has the same configuration as the simulation model of FIG. 5 except that the simulation model of the third modification has only the outer slots 18h.

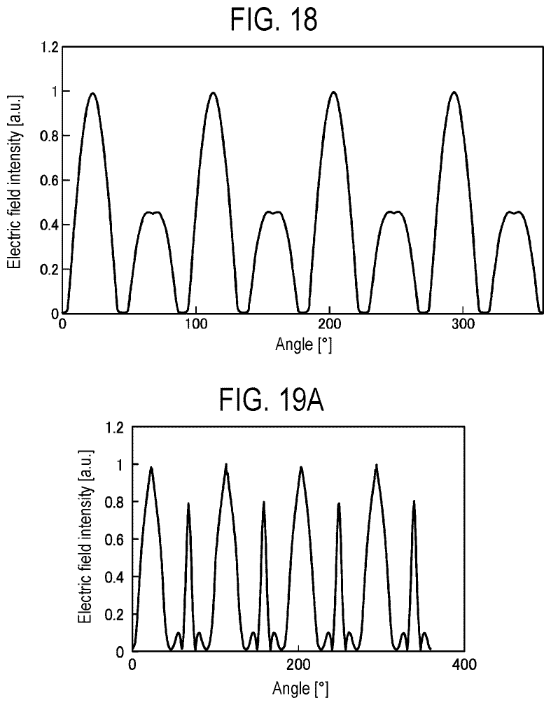

FIG. 18 is a graph showing the distribution of electric field intensity in the plasma generation space U calculated using a simulation model of the third modification of the plasma processing apparatus 10. The graph in FIG. 18 shows the distribution of electric field intensity directly below each outer slot 18h in the circumferential direction. Here, the position of the coaxial tube connection portion was set to the reference position.

As shown in FIG. 18, it was confirmed that in the third modification, an electromagnetic wave is emitted and an electric field is formed not only from the outer slots 18h where the impedance Zᵢₙ is infinite but also from the outer slots 18h where the impedance Zᵢₙ is zero. Therefore, applicant changed the position of the coaxial tube connection portion in the vertical direction and examined whether the electric field intensity directly below the outer slots 18h where the impedance Zᵢₙ is zero would decrease.

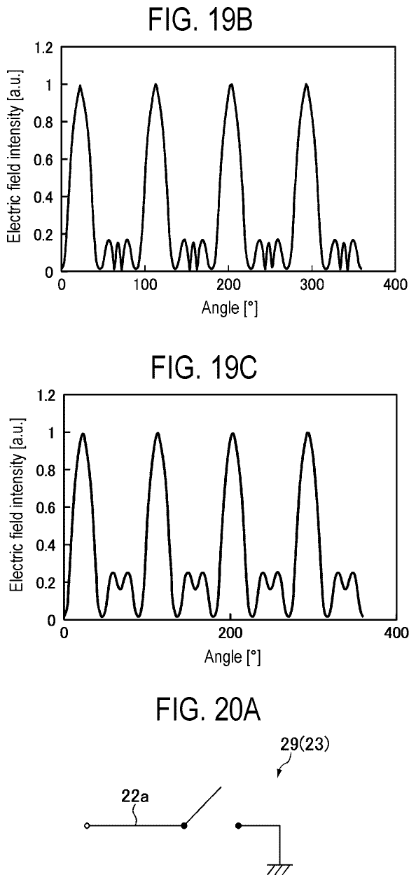

FIGS. 19A to 19C are graphs showing the distribution of electric field intensity in the plasma generation space U when the position of the coaxial tube connection portion is changed in the vertical direction in the simulation model of the third modification of the plasma processing apparatus 10. Each graph in FIGS. 19A to 19C also shows the distribution of electric field intensity directly below each outer slot 18h in the circumferential direction. Here, FIG. 19A shows a case in which the position of the coaxial tube connection portion is moved downward by 10 mm from the reference position, FIG. 19B shows a case in which the position of the coaxial tube connection portion is moved downward by 2.5 mm from the reference position, and FIG. 19C shows a case in which the position of the coaxial tube connection portion is moved upward by 5 mm from the reference position.

As shown in FIGS. 19A and 19B, it was confirmed that when the position of the coaxial tube connection portion is moved downward from the reference position, the electric field intensity directly below the outer slot 18h where the impedance Zᵢₙ is zero increases, especially near a center of each outer slot 18h in the circumferential direction. However, when the position of the coaxial tube connection portion is located below the reference position, it was also confirmed that the electric field intensity directly below the outer slot 18h where the impedance Zᵢₙ is zero decreases overall when the position of the coaxial tube connection portion is moved upward (moved closer to the reference position). As shown in FIG. 19C, it was also confirmed that when the position of the coaxial tube connection portion is moved upward from the reference position, the electric field intensity directly below the outer slot 18h where the impedance Zᵢₙ is zero increases overall.

From the above, applicant has found that even when the resonator 18 does not have the plurality of inner slots 18i, it is possible to change the electric field intensity directly below the outer slot 18h where the impedance Zᵢₙ is zero by moving the position of the coaxial tube connection portion. Since the electric field intensity directly below the outer slot 18h where the impedance Zᵢₙ is zero is changed according to the movement of the position of the coaxial tube connection portion, applicant has found that by optimizing the position of the coaxial tube connection portion, it is possible to reduce the intensity of the electromagnetic wave emitted from the outer slot 18h where the impedance Zᵢₙ is zero.

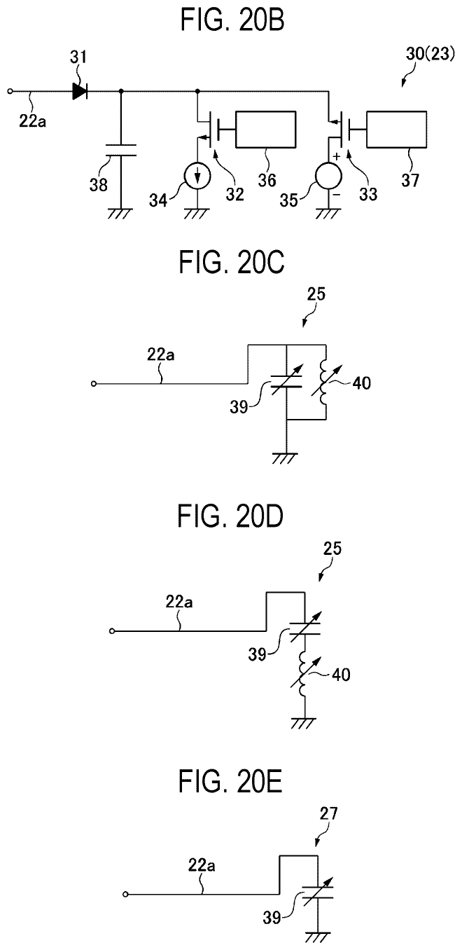

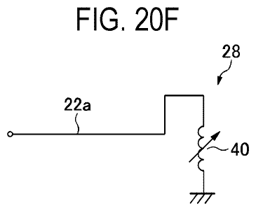

Furthermore, the switch 23 may be configured by, for example, a mechanical switch 29 (FIG. 20A) that can switch between short-circuiting to the ground and disconnecting the short-circuit, or may be configured by a switching circuit 30 (FIG. 20B).

The switching circuit 30 includes, for example, a diode 31, a first switching transistor 32, a second switching transistor 33, a current source 34, a voltage source 35, a signal generation circuit 36, a signal generation circuit 37, and a capacitor 38. The anode of the diode 31 is connected to the rod 22a of the coaxial tube 22. The cathode of the diode 31 is connected to the ground via the capacitor 38. The first switching transistor 32 and the second switching transistor 33 are disposed in parallel between the cathode of the diode 31 and the ground. The current source 34 is, for example, a constant current source and is disposed between the first switching transistor 32 and the ground. The voltage source 35 is, for example, a constant voltage source and is disposed between the second switching transistor 33 and the ground.

The signal generation circuit 36 is connected to a control terminal of the first switching transistor 32. The signal generation circuit 36 sends an oscillating control signal to the control terminal of the first switching transistor 32, thereby switching the first switching transistor 32 between an ON state (closed state) and an OFF state (open state). The signal generation circuit 37 is connected to a control terminal of the second switching transistor 33. The signal generation circuit 37 sends an oscillating control signal to the control terminal of the second switching transistor 33, thereby switching the second switching transistor 33 between an ON state and an OFF state. The first switching transistor 32 and the second switching transistor 33 are alternately set to the ON state by the signal generation circuits 36 and 37.

In the switching circuit 30, when the first switching transistor 32 is turned on, a forward current flows through the diode 31, and the corresponding outer slot 18h is short-circuited to the ground. On the other hand, when the second switching transistor 33 is turned on, a reverse voltage is applied to the diode 31, and the corresponding outer slot 18h is disconnected from the short-circuit to the ground.

Furthermore, the gradual impedance varying mechanism 25 may be configured, for example, by a variable capacitor 39 and a variable inductor 40 disposed in parallel between the rod 22a and the ground (FIG. 20C), or by a variable capacitor 39 and a variable inductor 40 disposed in series between the rod 22a and the ground (FIG. 20D). Furthermore, the gradual impedance varying mechanism 25 may be configured by a stub tuner (not shown) that is capable of changing the length l of the waveguide in the coaxial tube 22.

Furthermore, the variable capacitor mechanism 27 may be configured by a single variable capacitor 39 disposed between the rod 22a and the ground (FIG. 20E), or may be configured by a plurality of variable capacitors 39 disposed in series or in parallel between the rod 22a and the ground.

Furthermore, the variable inductor mechanism 28 may be configured by a single variable inductor 40 disposed between the rod 22a and the ground (FIG. 20F), or may be configured by a plurality of variable inductors 40 disposed in series or in parallel between the rod 22a and the ground.

According to the present disclosure in some embodiments, it is possible to improve the controllability of a density distribution of plasma generated inside a chamber.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus, comprising:
a chamber including a plasma generation space;
a first emitter formed in an annular shape and disposed above the chamber; and
a resonator configured to supply an electromagnetic wave to the first emitter,
wherein the resonator includes a waveguide through which the electromagnetic wave which is generated based on radio-frequency power supplied by a radio-frequency power supply propagates, and a plurality of first slots configured to electromagnetically couple the waveguide and the first emitter,
wherein the plurality of first slots are formed of a plurality of partial grooves extending in a circumferential direction of the first emitter above the first emitter,
wherein a plurality of impedance varying mechanisms for changing an impedance of each of the plurality of first slots are disposed so as to correspond to each of the plurality of first slots,
wherein a plurality of coaxial tubes are each disposed between each of the impedance varying mechanisms and the corresponding first slots, and
wherein each of the impedance varying mechanisms is attached to an end of the coaxial tube opposite the corresponding first slot.

2. The apparatus of claim 1, further comprising a second emitter formed in an annular shape, disposed above the chamber and inside the first emitter,
wherein the resonator further includes a plurality of second slots configured to electromagnetically couple the waveguide and the second emitter to each other, and
wherein the plurality of second slots are formed of a plurality of partial grooves extending in a circumferential direction of the second emitter above the second emitter.

3. The apparatus of claim 1, wherein a length from an end of the waveguide to a portion at which the coaxial tube is connected to a corresponding first slot is an integer multiple of a half wavelength of the electromagnetic wave.

4. The apparatus of claim 3, wherein a length from the end of the waveguide to the end of the coaxial tube is an integer multiple of a quarter wavelength of the electromagnetic wave.

5. The apparatus of claim 1, wherein the plurality of first slots are evenly spaced apart from each other along the circumferential direction of the first emitter.

6. The apparatus of claim 5, wherein the plurality of coaxial tubes are evenly spaced apart from each other along the circumferential direction of the first emitter so as to correspond to the plurality of first slots.

7. The apparatus of claim 1, wherein states of the plurality of impedance varying mechanisms are alternately switched between short-circuiting to a ground and disconnecting the short-circuit along the circumferential direction.

8. The apparatus of claim 1, wherein the impedance varying mechanism is one of a gradual impedance varying mechanism configured to gradually change an impedance of the gradual impedance varying mechanism, a variable capacitor mechanism configured to gradually change a capacitance of the variable capacitor mechanism, and a variable inductor mechanism configured to gradually change an inductance the variable inductor mechanism.

9. A plasma generation method for a plasma processing apparatus, wherein the plasma processing apparatus includes: a chamber having a plasma generation space, an emitter formed in an annular shape and disposed above the chamber, and a resonator configured to supply an electromagnetic wave to the emitter,
wherein the resonator includes a waveguide through which the electromagnetic wave which is generated based on radio-frequency power supplied by a radio-frequency power supply propagates, and a plurality of slots configured to electromagnetically couple the waveguide and the emitter,
wherein the plurality of slots are formed of a plurality of partial grooves extending in a circumferential direction of the emitter above the emitter,
wherein a plurality of impedance varying mechanisms for changing an impedance of each of the plurality of slots are disposed so as to correspond to each of the plurality of slots,
wherein a plurality of coaxial tubes are each disposed between each of the impedance varying mechanisms and the corresponding slots, and
wherein each of the impedance varying mechanisms is attached to an end of the coaxial tube opposite the corresponding slot, and
the plasma generation method comprises:
generating the electromagnetic wave based on the radio-frequency power supplied by the radio-frequency power supply; and
emitting the electromagnetic wave from the emitter into the plasma generation space,
wherein the impedance of the corresponding slot is changed by the impedance varying mechanism.
